(19) United States
(12) Patent Application Publication
(10) Pub. No.: US 2019/0088618 A1
(43) Pub. Date: Mar. 21, 2019

(54) METHOD OF MANUFACTURING A SEMICONDUCTOR DEVICE

(71) Applicant: Toshiba Memory Corporation, Tokyo (JP)

(72) Inventors: Kazumichi TSUMURA, Shinagawa Tokyo (JP); Kazuyuki HIGASHI, Yokohama Kanagawa (JP)

(21) Appl. No.: 15/905,470

(22) Filed: Feb. 26, 2018

(30) Foreign Application Priority Data
Sep. 15, 2017 (JP) 2017-178257

(51) Int. Cl. H01L 23/00

(52) U.S. Cl. CPC H01L 24/89; H01L 2224/05683; H01L 2224/80895; H01L 2224/80896; H01L 2224/80013; H01L 2224/05649; H01L 2224/05624; H01L 2224/05672; H01L 2224/05618; H01L 2224/05679; H01L 2224/0567; H01L 2224/05671; H01L 2924/01039; H01L 2924/01043; H01L 24/05

(57) ABSTRACT

A method of manufacturing a semiconductor device includes forming a first metal film on a first insulating region and a first metal region directly adjacent to the first insulating region, wherein the first metal film comprises a metal other than the metal of the first metal region, forming a second metal film on a second insulating region and a second metal region directly adjacent to the second insulating region, wherein the second metal film comprises a metal other than the metal of the second metal region, bringing the first metal film and the second metal film into contact with each other, and heat treating the first substrate and the second substrate and thereby electrically connecting the first metal region and the second metal region to each other and simultaneously forming an insulating interface film between the first insulating region and the second insulating region.

### CROSS-REFERENCE TO RELATED APPLICATION

This application is based upon and claims the benefit of priority from Japanese Patent Application No. 2017-178257, filed Sep. 15, 2017, the entire contents of which are incorporated herein by reference.

### FIELD

Embodiments described herein relate generally to a method of manufacturing a semiconductor device.

### BACKGROUND

A technique (wafer-to-wafer (W2W) metal bonding) of joining a plurality of semiconductor wafers and bonding electrodes formed on surfaces of respective semiconductor wafers to each other has been developed. In such a technique, the electrodes on the surfaces of the semiconductor wafers are buried in an insulating film and then are exposed before they are joined. Accordingly, the plurality of semiconductor wafers are aligned so that the respective electrodes are bonded to each other.

However, on the semiconductor wafer, adjacent electrodes maybe short circuited via a bonding interface or time dependent dielectric breakdown (TDDB) between the electrodes may be deteriorated. This leads to a problem of deterioration of electric characteristics and reliability.

Further, on the surface of the semiconductor wafer immediately before bonding is performed, a plurality of different materials such as a Cu electrode and an insulating film are exposed. Accordingly, when plasma treatment, cleaning, or the like is performed in order to bring a surface of an insulating film into a state suitable for bonding, a problem that an electrode surface is oxidized by cleaning or the electrode material is re-sputtered by plasma treatment occurs.

### DESCRIPTION OF THE DRAWINGS

FIG. 1 is a cross-sectional view illustrating a manufacturing process of a first semiconductor member.

FIG. 2 is a cross-sectional view illustrating the manufacturing process of the first semiconductor member, continued from FIG. 1.

FIG. 3 is a cross-sectional view illustrating the manufacturing process of the first semiconductor member, continued from FIG. 2.

FIG. 4 is a cross-sectional view illustrating the manufacturing process of the first semiconductor member, continued from FIG. 3.

FIG. 5 is a cross-sectional view illustrating the manufacturing process of the first semiconductor member, continued from FIG. 4.

FIG. 6 is a cross-sectional view illustrating the manufacturing process of the first semiconductor member continued from FIG. 5.

FIG. 7 is a cross-sectional view illustrating the manufacturing process of the first semiconductor member, continued from FIG. 6.

FIG. 8 is a cross-sectional view illustrating the manufacturing process of the first semiconductor member, continued from FIG. 7.

FIG. 9 is a cross-sectional view illustrating the manufacturing process of the first semiconductor member, continued from FIG. 8.

FIG. 10 is a cross-sectional view illustrating a configuration example of a second semiconductor member.

FIG. 11 is a cross-sectional view illustrating a process of joining the first semiconductor member and the second semiconductor member.

FIG. 12 is a cross-sectional view illustrating a process of joining the first semiconductor member and the second semiconductor member, continued from FIG. 11.

### DETAILED DESCRIPTION

Embodiments provide a manufacturing method of a semiconductor device capable of preventing deterioration of electrical characteristics and reliability of a semiconductor device when a plurality of semiconductor wafers are joined, and allows facilitation of pretreatment of the devices useful for joining them together.

In general, according to one embodiment, a method of manufacturing a semiconductor device includes forming a first metal film on a first insulating region and a first metal region directly adjacent to the first insulating region, wherein the first metal film comprises a metal other than the metal of the first metal region, forming a second metal film on a second insulating region and a second metal region directly adjacent to the second insulating region, wherein the second metal film comprises a metal other than the metal of the second metal region, bringing the first metal film and the second metal film into contact with each other so that the first surface of the first substrate faces the second surface of the second substrate, and heat treating the first substrate and the second substrate and thereby electrically connecting the first metal region and the second metal region to each other and simultaneously forming an insulating interface film between the first insulating region and the second insulating region.

Hereinafter, an embodiment of the present disclosure will be described with reference to the drawings. The embodiment does not limit the present disclosure. In the following embodiment, a vertical direction of a semiconductor substrate indicates a relative direction in a case where a surface on which a semiconductor element is provided is considered as upward, and may be different from a vertical direction according to gravitational acceleration. The drawings are schematic or conceptual, and a ratio of each portion is not necessarily the same as that in an the actual one. In the specification and drawings, elements similar to those described previously with reference to the drawings are assigned the same reference numerals, and detailed description thereof will be omitted as appropriate.

In the manufacturing method of the semiconductor device according to the embodiment, a semiconductor device such as an arithmetic device and a memory device is manufactured by joining a plurality of semiconductor substrates. On a plurality of joined semiconductor substrates, electronic circuits including circuit elements such as transistors and wiring portions for connecting the circuit elements are provided in a single layer or stacked layers. The electronic circuits are electrically connected to each other between the plurality of joined semiconductor substrates. This is because a wiring connection portion of one semiconductor substrate and a wiring connection portion of the other semiconductor substrate are bonded to each other when the semiconductor substrates are joined to each other. The wiring connection portion may be a metal wiring or a penetrating electrode (through silicon via (TSV)) formed to penetrate through the semiconductor substrate.

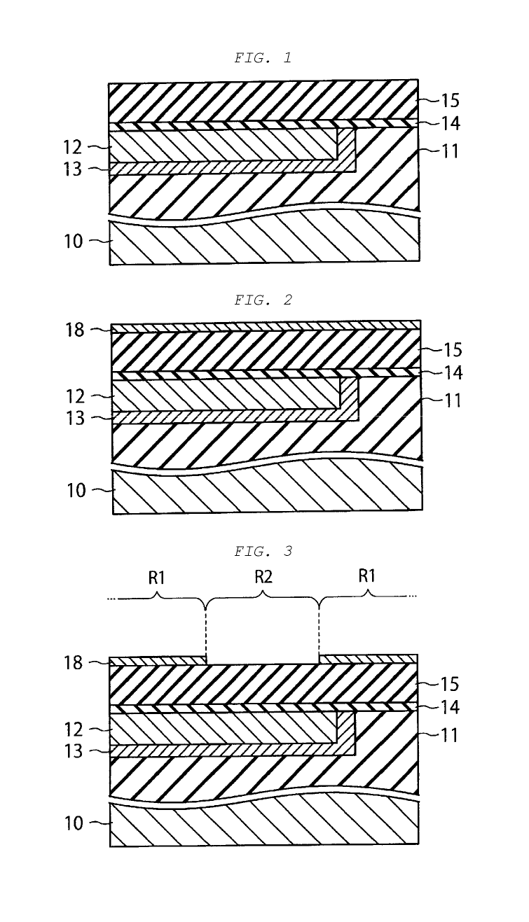

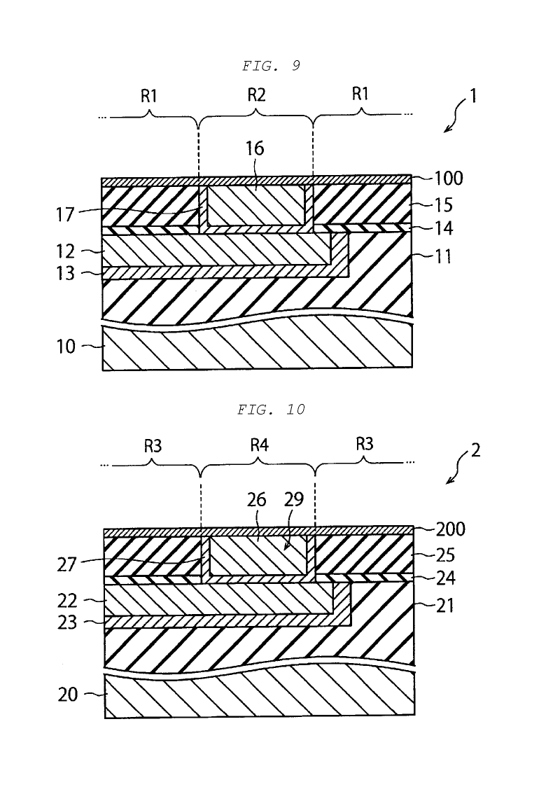

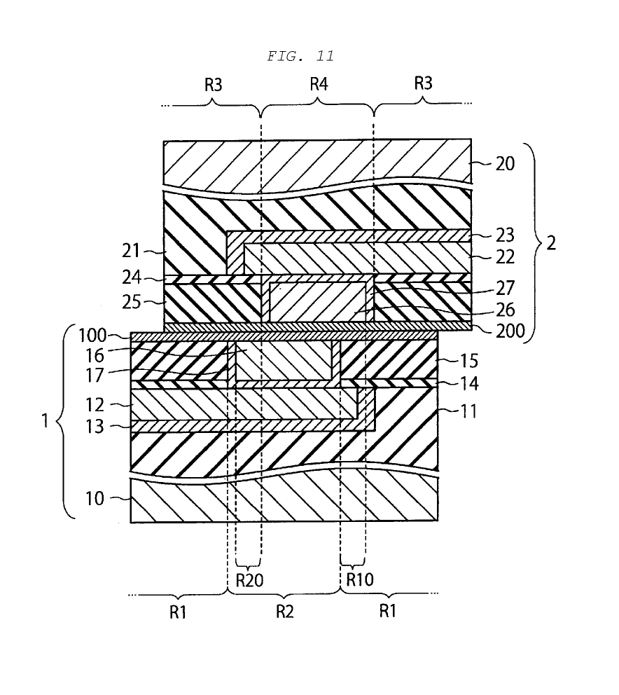

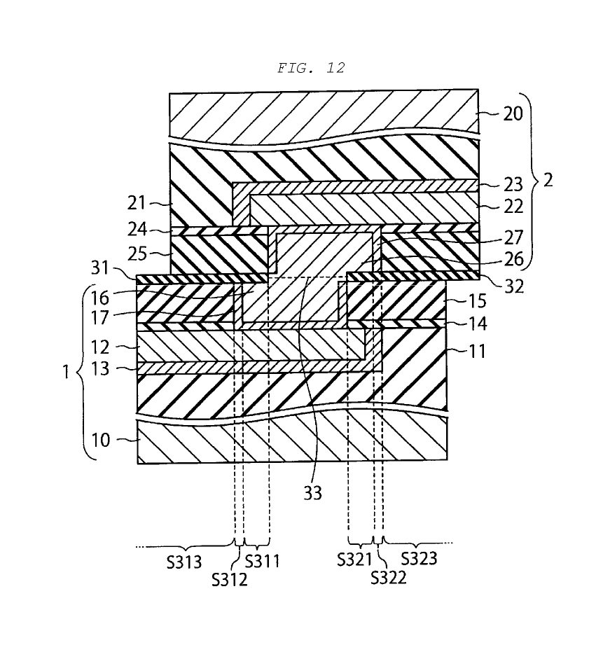

A manufacturing method of a semiconductor device according to the embodiment will be described with reference to FIGS. 1 to 12. FIGS. 1 to 9 are cross-sectional views illustrating a manufacturing process of a first semiconductor member 1. FIG. 10 is a cross-sectional view illustrating a configuration example of a second semiconductor member 2. FIGS. 11 and 12 are cross-sectional views illustrating a process of joining the first semiconductor member 1 and the second semiconductor member 2.

First, a method of forming the first semiconductor member 1 will be described. First, as illustrated in FIG. 1, an insulating film 11, a wiring portion 12, a first diffusion preventing film 13, and a second diffusion preventing film 14 are formed above the first semiconductor substrate 10 using a semiconductor device manufacturing technique such as chemical vapor deposition (CVD), sputtering, lithography, etching, plating, chemical mechanical polishing (CMP), or the like. In this case, the upper surfaces of the insulating film 11 and the wiring portion 12 are formed so as to be substantially flush with each other.

As the insulating film 11, an insulator such as SiO₂ is used. Although not illustrated, an electronic circuit is formed in the insulating film 11. As illustrated in FIG. 1, the first semiconductor substrate 10 is disposed below the insulating film 11.

The wiring portion 12 is electrically connected to the electronic circuit formed in the insulating film 11. Cu is contained in the wiring portion 12 as a main component (50 at% or more of the whole).

The first diffusion preventing film 13 functions as a barrier layer and prevents diffusion of Cu contained in the wiring portion 12 into the insulating film 11. The first diffusion preventing film 13 is formed of a conductor such as Ti, Ta, Ru or nitride thereof (TiN, TaN, and RuN) , for example.

The second diffusion preventing film 14 functions as a barrier layer and prevents diffusion of Cu contained in the wiring portion 12 into an interlayer insulating film 15. The second diffusion preventing film 14 is formed of an insulator such as SiC, SiN or SiCN, for example. With this, for example, it is possible to prevent short circuiting between the plurality of wiring portions 12 adjacent to each other in the paper surface direction of FIG. 1.

Next, as illustrated in FIG. 1, the interlayer insulating film 15 is formed above the surface of the first semiconductor substrate 10, that is, on the second diffusion preventing film 14. The interlayer insulating film 15 as a first insulating film is formed of an oxide film containing SiO₂, SiOC, or the like as a main component using CVD or the like.

Next, as illustrated in FIG. 2, a resist film 18 is coated on the interlayer insulating film 15. Next, as illustrated in FIG. 3, a pattern for forming a wiring connection portion 16 as the first wiring film is formed in the resist film 18 by a lithography technique. In this case, a resist film 18 in a remaining region (first region) R1 of the interlayer insulating film 15 remains. The resist film 18 in a formation region (second region) R2 of the wiring connection portion 16 is removed.

Next, as illustrated in FIG. 4, a dry etching treatment is performed using the resist film 18 as a mask. By the dry etching treatment, the interlayer insulating film 15 and the second diffusion preventing film 14 are processed and a groove 19 (opening) is formed in the interlayer insulating film 15 of the formation region R2 of the wiring connecting portion 16. The dry etching treatment is performed until the surface of the wiring portion 12 is exposed. With this, the interlayer insulating film 15 of the second region R2 on the surface of the first semiconductor substrate 10 is removed and the interlayer insulating film 15 of the first region R1 remains.

Next, as illustrated in FIG. 5, the resist film 18 remaining on the interlayer insulating film 15 and residual deposits generated by the dry etching treatment are removed. For example, an ashing treatment using oxygen plasma or a cleaning treatment using chemical solution dissolving the resist is performed.

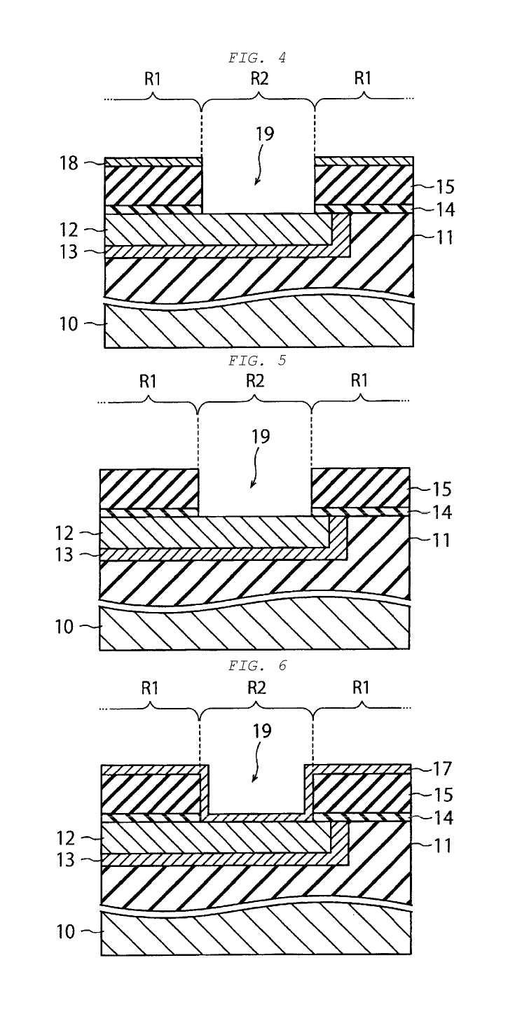

Next, as illustrated in FIG. 6, a third diffusion preventing film 17 which functions as a barrier layer and is formed on the side surfaces of the interlayer insulating film 15 (inner wall sides of the groove 19) and the wiring portion 12 of the second region R2. The third diffusion preventing film 17 as a first barrier film is formed by sputtering Ti, Ta, Ru or nitride thereof (TiN, TaN, RuN) or the like in an Ar/N₂ atmosphere. The third diffusion preventing film 17 can prevent diffusion of Cu contained in the wiring connecting portion 16 to be described later into the interlayer insulating film 15.

Next, as illustrated in FIG. 7, the wiring connecting portion 16 is deposited on the third diffusion preventing film 17 by an electrolytic plating method. The wiring connection portion 16 contains, for example, Cu as a main component. The wiring connection portion 16 is electrically connected to the wiring portion 12 via the third diffusion preventing film 17.

After the wiring connection portion 16 is formed, heat treatment such as annealing treatment may be performed on the first semiconductor substrate 10. With this, the crystalline structure of the wiring connection portion 16 can be improved and chemical and physical stability of the wiring connection portion 16 can be improved.

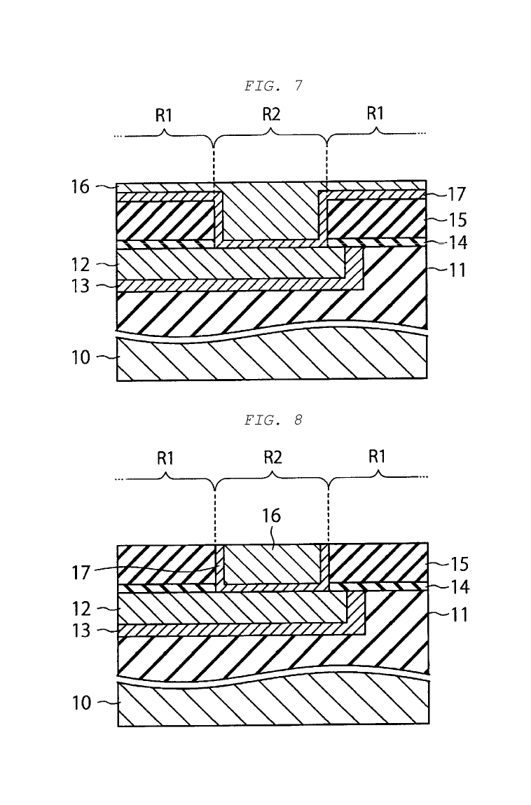

Next, as illustrated in FIG. 8, the third diffusion preventing film 17 and the wiring connecting portion 16 are polished and planarized by a technique such as CMP (chemical mechanical polishing) until the interlayer insulating film 15 is exposed. As a result, the third diffusion preventing film 17 and the wiring connecting portion 16 on the interlayer insulating film 15 are removed and the surface of the wiring connecting portion 16 is substantially flush with the surface of the interlayer insulating film 15.

The interlayer insulating film 15 remains in the first region R1 of the surface of the first semiconductor substrate 10. The groove 19 is formed in the second region R2 other than the first region R1 of the surface of the first semiconductor substrate 10, and the third diffusion preventing film 17 and the wiring connecting portion 16 are formed in the groove 19.

The wiring connection portion 16 functions as an electrode for electrically connecting the electronic circuits which are respectively formed on the first and second semiconductor members 1 and 2 to be joined to each other. A planar layout of the wiring connection portion 16 can be arbitrarily designed.

Next, as illustrated in FIG. 9, a metal film 100 is formed on the interlayer insulating film 15, the wiring connecting portion 16, and the third diffusion preventing film 17 by the CVD method. The metal film 100 as the first metal film is preferably formed of a metal material which is more easily oxidized than the wiring connection portion 16. For example, in a case where the wiring connection portion 16 is copper, the metal film 100 is formed of at least one metal material selected from the group consisting of Mn, Al, V, Zn, Nb, Zr, Cr, Y, Tc and Re. Preferably, the metal material of the metal film 100 is Mn. The metal film 100 may be alloy of a plurality of metal materials selected from the group described above. A thickness of the metal film 100 is, for example, several nanometers. Hereinafter, description will be made by assuming that the material of the metal film 100 is Mn.

The first semiconductor member 1 and the second semiconductor member 2 maybe exposed to the atmosphere during a period from forming of the metal film 100 to joining of the first semiconductor member 1 and the second semiconductor member 2. Oxide (CuO in a case where the wiring connection portion 16 contains Cu) is formed on the surface of the wiring connection portion 16 by being exposed to the atmosphere. In this case, when the material of the metal film 100 is more easily oxidized than that of the wiring connection portion 16, the oxide on the surface of the wiring connection portion 16 is easily reduced. The oxide on the surface of the wiring connection portion 16 is reduced so as to make it possible to reduce an electrical resistance of the wiring connection portions 16 and 26.

By the processes described, the first semiconductor member 1 is formed.

Next, a method of forming a second semiconductor member 2 will be described. The second semiconductor member 2 may be formed by the same method as that of the first semiconductor member 1.

FIG. 10 is a cross-sectional view illustrating a configuration example of the second semiconductor member 2. An insulating film 21, a wiring section 22, a first diffusion preventing film 23, a second diffusion preventing film 24, an interlayer insulating film 25, a wiring connection portion 26, a third diffusion preventing film 27, and a metal film 200 that are formed on the second semiconductor substrate 20 are formed similarly to the insulating film 11, the wiring portion 12, the first diffusion preventing film 13, the second diffusion preventing film 14, the interlayer insulating film 15, the wiring connection portion 16, the third diffusion preventing film 17, and the metal film 100 of the first semiconductor member 1, respectively.

That is, first, the insulating film 21, the wiring portion 22, the first diffusion preventing film 23, and the second diffusion preventing film 24 are formed on the second semiconductor substrate 20. Next, the interlayer insulating film 25 as a second insulating film is formed above the surface of the second semiconductor substrate 20 (on the second diffusion preventing film 24). Next, the interlayer insulating film 25 is processed by using the lithography technique and the dry etching technique, and a groove 29 (opening) is formed in the interlayer insulating film 25 so that the surface of the wiring portion 22 is exposed. In a third region R3 of the surface of the second semiconductor substrate 20, the interlayer insulating film 15 remains. A groove 29 is formed in a fourth region R4, other than the third region R3, of the surface of the second semiconductor substrate 20. Next, a third diffusion preventing film 27 as a second barrier film is formed on the side surfaces of the interlayer insulating film 25 (inner sides of the groove 29) and above the fourth region R4. Next, the wiring connecting portion 26 is deposited on the third diffusion preventing film 27 to form the wiring connecting portion 26. Next, the surface on the bonding interface side is planarized until the surface of the interlayer insulating film 25 is exposed. As a result, on the surface of the second semiconductor substrate 20, the wiring connecting portion 26 as the second wiring film and the third diffusion preventing film 27 are formed in the fourth region R4 (groove 29) different from the third region R3. Next, a metal film 200 as a second metal film is formed on the interlayer insulating film 25, the wiring connecting portion 26, and the third diffusion preventing film 27. With this, the second semiconductor member 2 is formed.

The metal material and the thickness of the metal film 200 may be the same as those of the metal film 100. In a case where the total thicknesses of the metal films 100 and 200 is large, there is a possibility that the metal films 100 and 200 remain insufficiently reacted after heat treatment, which will be described later, and deteriorate electrical characteristics of the semiconductor device. Accordingly, the total thickness of the metal films 100 and 200 is preferably, for example, 10 nm or less.

The first semiconductor member 1 and the second semiconductor member 2 may be exposed to the atmosphere during the period from forming of the metal film 200 to joining of the first semiconductor member 1 and the second semiconductor member 2. Oxide is formed on the surface of the wiring connection portion 26 by being exposed to the atmosphere. For example, in a case where the wiring connection portion 26 contains Cu, the formed oxide is CuO. In this case, when the material of the metal film 200 is more easily oxidized than that of the wiring connection portion 26, the oxide on the surface of the wiring connection portion 26 is easily reduced. The oxide on the surface of the wiring connection portion 26 is reduced so as to make it possible to reduce the electrical resistance of the wiring connection portions 16 and 26.

Next, pretreatment for bonding is performed on the metal films 100 and 200. As described above, when the first semiconductor member 1 and the second semiconductor member 2 are exposed to the atmosphere, an oxide film is formed on the surfaces of the metal films 100 and 200. For example, in a case where the metal films 100 and 200 are made of Mn, MnO is formed on the surfaces of the metal films 100 and 200.

In pretreatment, for example, N₂ plasma treatment is performed on the metal films 100 and 200. With this, a dangling bond is generated in an oxide film on the surfaces of the metal films 100 and 200 and bonding between the first semiconductor member 1 and the second semiconductor member 2 can be made stronger. It is not limited to N₂ plasma treatment, but a plasma treatment using another gas may be performed in pretreatment. Further, water cleaning treatment may be performed on the metal films 100 and 200. With this, it is possible to remove impurities and the like on the surfaces of the metal films 100 and 200. It is not limited to water cleaning treatment, but may be cleaning treatment using chemical solution or the like.

Next, the surface of the first semiconductor substrate 10 and the surface of the second semiconductor substrate 20 are made to oppose each other and the wiring connection portion 16 and the wiring connection portion 26 are brought into contact with each other. That is, the first semiconductor member 1 (metal film 100) and the second semiconductor member 2 (metal film 200) are aligned and brought into contact with each other so that the wiring connecting portion 16 and the wiring connecting portion 26 are opposed to each other (joined).

FIG. 11 and FIG. 12 are cross-sectional views illustrating a process of joining the first semiconductor member 1 and the second semiconductor member 2. FIGS. 11 and 12 illustrate a state in which positional deviation occurs at the time of joining the first semiconductor member 1 and the second semiconductor member 2. In this case, as illustrated in FIG. 11, a region R20 where the wiring connecting portion 16 and the interlayer insulating film 25 oppose each other via the metal films 100 and 200 interposed therebetween and a region R10 where the wiring connecting portion 26 and the interlayer insulating film 15 oppose each other via the metal films 100 and 200 interposed therebetween are present. In a case where the first semiconductor member 1 and the second semiconductor member 2 are exposed to the atmosphere at the time when joining the first and second semiconductor members 1 and 2, fusion bonding or surface activated bonding (SAB) can be used.

Next, heat treatment such as annealing treatment is performed on the joined first semiconductor member 1 and the second semiconductor member 2. The first semiconductor member 1 and the second semiconductor member 2 are heated for 1 hour, for example, at 400° C. In this case, the metal films 100 and 200 diffuse into the wiring connecting portions 16 and 26 to a certain extent and almost disappear between the wiring connecting portion 16 and the wiring connecting portion 26. Furthermore, the wiring connection portions 16 and 26 expand. With this, the wiring connecting portions 16 and 26 are bonded at a connecting portion 33 to be electrically connected together at the bonding interface illustrated in FIG. 12. An electronic circuit formed in the first semiconductor member 1 is electrically connected to an electronic circuit formed in the second semiconductor member 2. The metal films 100 and 200 may remain somewhat at the connecting portion 33. In a case where the materials of the metal films 100 and 200 are diffused into the wiring connection portions 16 and 26, the electrical resistance of the wiring connection portions 16 and 26 slightly increases. However, there is no problem as long as the wiring connection portions 16 and 26 have a low resistance of several ohms or less, for example.

By the heat treatment described above, as illustrated in FIG. 12, at the bonding interface between the first semiconductor member 1 and the second semiconductor member 2, an interface film 31 is formed at a bonding interface S311 between the wiring connecting portion 16 and the interlayer insulating film 25, at a bonding interface S312 between the third diffusion preventing film 17 and the interlayer insulating film 25, and at a bonding interface S313 between the interlayer insulating film 15 and the interlayer insulating film 25. An interface film 32 is formed at a bonding interface S321 between the wiring connecting portion 26 and the interlayer insulating film 15, at a bonding interface S322 between the third diffusion preventing film 27 and the interlayer insulating film 15, and at a bonding interface 5323 between the interlayer insulating film 15 and the interlayer insulating film 25.

The interface film 31 has the a function of preventing diffusion of Cu contained in the wiring connecting portion 16 into the interlayer insulating film 25. The interface film 31 is, for example, MnSiOₓ. The interface film 31 may be at least one compound selected from the group consisting of αₓO_{y}, αₓSi_{y}O_{z}, αₓSi_{y}O_{z}, αₓC_{y}O_{z}and αₓF_{y}O_{z}. Here, α is a material of the metal film 100, and in the embodiment, description will be made by regarding the α as Mn. For example, in a case where the main component of the metal films 100 and 200 are Mn and the main components of the interlayer insulating films 15 and 25 are SiO₂, the interface film 31 is MnSiOₓ. In a case where the wiring connection portions 16 and 26 are made of a plurality of types of metal materials, the interface film 31 may contain a plurality of types of materials.

The interface film 32 has a function of preventing diffusion of Cu contained in the wiring connecting portion 26 into the interlayer insulating film 15. Similar to the interface film 31, the interface film 32 contains at least one compound selected from the group consisting of αₓO_{y}, αₓSi_{y}O_{z}, αₓC_{y}O_{z} and αₓF_{y}O_{z}. For example, in a case where the main components of the metal films 100 and 200 are Mn and the main components of the interlayer insulating films 15 and 25 are SiO₂, the interface film 32 is MnSiOₓ. In a case where the wiring connection portions 16 and 26 are made of a plurality of types of metal materials, the interface film 32 may contain a plurality of types of materials.

The interface film 31 and the interface film 32 have an electrical insulating property. As a result of this property, it is possible to prevent short-circuiting of wiring and elements on opposed sides of the interface films 31 and 32 at the bonding interface where Cu is easily diffused. Thus, the interface films 31 and 32 prevent diffusion of Cu at the bonding interface. Accordingly, it is possible to prevent short-circuiting between adjacent wirings and elements and deterioration of TDDB between wirings and elements.

As a result of heat treatment, the interface film 31 is formed at the bonding interface S311 between the wiring connecting portion 16 and the interlayer insulating film 25 in a self-aligned manner. The materials of the metal films 100 and 200 that did not react with the insulating layer on which they were formed to form an interface film, (interface film 31 was not formed) at the time of heat treatment diffuse into the wiring connection portions 16 and 26 during the heat treatment. By the heat treatment described above, also at the interface S312 between the third diffusion preventing film 17 and the interlayer insulating film 25 and at the interface S313 between the interlayer insulating film 15 and the interlayer insulating film 25, the interface film 31 is similarly formed in a self-aligned manner.

The interface film 32 is also formed similarly to the interface film 31. That is, the interface film 32 is formed at the interface S321 between the wiring connection portion 26 and the interlayer insulating film 15 in a self-aligned manner. Furthermore, at the interface S322 between the third diffusion preventing film 27 and the interlayer insulating film 15 and the bonding interface S323 between the interlayer insulating film 15 and the interlayer insulating film 25, the interface film 32 is formed similarly in a self-aligned manner. As a result, the interface film 32 prevents diffusion of the metal in the wiring connection portion 26 from diffusing into the interlayer insulating film 15, and the interface film 31 prevents diffusion of the metal in the wiring connection portion 16 from diffusing into the interlayer insulating film 25.

Accordingly, even in a case where positional deviation between the wiring connection portions 16, 26 occurs at the time of joining the first semiconductor member 1 and the second semiconductor member 2, the interface films 31 and 32 can prevent diffusion of Cu from the wiring connection portions 16 and 26 into the interlayer insulating films 15 and 25. Further, as illustrated in FIG. 11, the interface films 31 and 32 are formed at the bonding interface. Accordingly, the interface films 31 and 32 are not present on the same plane as the third diffusion preventing films 17 and 27. That is, the interface films 31 and 32 do not overlap with the third diffusion preventing films 17 and 27 at one side of the wiring connection portions 16, 26 when viewed in a direction perpendicular to the surface of the semiconductor substrate or the semiconductor member. Accordingly, as can be seen from FIG. 12, in the region where the wiring connecting portion 16 and the wiring connecting portion 26 are connected, a region where the third diffusion preventing films 17 and 27 having relatively higher resistance than the wiring connecting portions 16 and 26 are not provided is present. It is possible to secure a wider region where the wiring connecting portion 16 and the wiring connecting portion 26 are connected to each other, so that the increase in electrical resistance can be further prevented. One of the materials of the metal films 100 and 200 may be Mn and the other may be MnO, or both of the materials of the metal films 100 and 200 may be MnO. In this case, MnO forms MnSiOₓ as the interface films 31 and 32 after heat treatment, similarly to Mn.

The first and second semiconductor substrates 10 and 20 may be processed in a vacuum atmosphere from formation of the metal films 100 and 200 until contact between the first semiconductor member 1 and the second semiconductor member 2. In this case, the surfaces of the metal films 100 and 200 are hardly oxidized. Accordingly, it is possible to prevent an increase in electrical resistance of the connection portion 33 after heat treatment.

In the manufacturing method of the semiconductor device according to the embodiment, both of the metal films 100 and 200 are formed on the first and second semiconductor members 1 and 2. However, only one of the metal films 100 and 200 may be formed on the first or second semiconductor members 1 and 2. Even in this case, the interface films 31 and 32 can be formed. In this case, N₂ plasma treatment is also performed on the surface of the first semiconductor substrate 10 (or the second semiconductor substrate 20) without the metal film 100 (or 200) thereon in the pretreatment process of bonding. In this case, Cu contained in the wiring connection portion 16 (or 26) can be re-sputtered onto the interlayer insulating film 15 (or 25). Accordingly, Cu may remain on the interface films 31 and 32 between the interlayer insulating film 15 and the interlayer insulating film 25. In this case, short-circuiting or deterioration of TDDB between wirings and elements are likely to occur in some cases. Accordingly, while one of the metal films 100 and 200 may be formed, it is more preferable to form both of the metal films 100 and 200.

As described above, according to the manufacturing method of the semiconductor device according to the embodiment, the metal film 100 (for example, Mn) is formed on the interlayer insulating film 15 and the wiring connection portion 16 (for example, Cu) in the first semiconductor member 1. The metal film 200 (for example, Mn) is formed on the interlayer insulating film 25 and the wiring connection portion 26 (for example, Cu) in the second semiconductor member 2. With this, when the first semiconductor member 1 and the second semiconductor member 2 are joined to each other, the metal films 100 and 200 are brought into contact with each other and the interface films 31 and 32 (for example, MnSiO₂) are formed after heat treatment is performed. As a result, diffusion of Cu from the wiring connection portion 26 into the interlayer insulating film 15 can be prevented and diffusion of Cu from the wiring connection portion 16 into the interlayer insulating film 25 can be prevented, while a low resistance connection of the wiring connection portions is achieved.

In a case where the metal film 200 is not formed, when the positions of the wiring connection portions 16 and 26 are deviated, the material (for example, Cu) of the wiring connection portions 16 and 26 of one of the semiconductor members is brought into contact with the material (for example, SiO₂) of the interlayer insulating films 15 and 25 of the other semiconductor member. In this case, Cu may diffuse into the interlayer insulating films 15 and 25 from the wiring connection portions 16 and 26. At the bonding interface between the interlayer insulating films 15 and 25, Cu easily diffuses along the bonding interface due to existence of minute defects.

In contrast, the interface films 31 and 32 according to the embodiment prevent diffusion of Cu along the bonding interface. With this, it is possible to prevent short-circuiting and deterioration of TDDB between adjacent wirings and elements and it is possible to improve electric characteristics and reliability of the semiconductor device.

The interface films 31 and 32 form in a self-aligned manner. Accordingly, as compared with a case of forming a barrier film of SiN or the like over the entire surface of the interlayer insulating films 15 and 25, it is possible for the interlayer insulating film to have a low dielectric constant. It is unnecessary to form the interlayer insulating films 15 and 25 using a new insulating material for preventing the diffusion of Cu and thus, cost can be reduced.

When pretreatment is performed before joining to the metal films 100 and 200, the Cu of the wiring connection portions 16 and 26 is covered with the metal films 100 and 200. With this, it is possible to prevent re-sputtering or oxidation of Cu in the wiring connection portions 16 and 26 even when existing N₂ plasma treatment or water cleaning treatment is used. Thus, pretreatment before joining is easily performed. The material to be processed is one kind of the metal films 100 and 200 and thus, optimization of pretreatment also becomes easy.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
providing a first substrate comprising a first surface including a first insulating region and at least one first metal region directly adjacent to the first insulating region;
forming a first metal film on the first insulating region and the first metal region, wherein the first metal film comprises a metal other than the metal of the first metal region;
providing a second substrate comprising a second surface including a second insulating region and at least one second metal region directly adjacent to the second insulating region;
forming a second metal film on the second insulating region and the second metal region, wherein the second metal film comprises a metal other than the metal of the second metal region;
bringing the first metal film and the second metal film into contact with each other so that the first surface of the first substrate faces the second surface of the second substrate; and
heat treating the first substrate and the second substrate and thereby electrically connecting the first metal region and the second metal region to each other and simultaneously forming an insulating interface film between the first insulating region and the second insulating region.

2. The method according to claim 1, wherein a portion of the first metal region faces the second insulating region.

3. The method according to claim 2, wherein a first barrier layer is interposed between the first metal region and the first insulating region, and a portion of the first barrier layer extends to the first surface of the first substrate on opposite sides of the first metal region; and
the insulating interface film extends across the portion of the first barrier layer adjacent to the portion of the first metal region facing the second insulating region.

4. The method according to claim 3, wherein the portion of the first barrier layer extending to the first surface of the first substrate adjacent to the portion of the first metal region which does not face the second insulating region is not covered by the insulating film.

5. The method according to claim 1, further comprising exposing at least one of first metal film and the second metal film to a plasma before bringing the first metal film and the second metal film into contact with each other.

6. The method according to claim 1, further comprising cleaning or performing plasma treatment on at least one of first metal film and the second metal film before bringing the first metal film and the second metal film into contact with each other.

7. The method according to claim 1, wherein the first metal film is formed of a metal that is more easily oxidized than the metal of the first metal region; and
the second metal film is formed of a metal that is more easily oxidized than the metal of the second metal region.

8. The method according to claim 1, wherein the insulating interface film is comprises a compound formed of the material of the first and second metal films and the first and second insulating regions.

9. The method according to claim 1, wherein the electrically connected first metal region and the second metal region includes the material of the first and second metal films therein.

10. The method according to claim 1, wherein at least one of the first metal film and second metal film comprises a metal oxide.

11. The method according to claim 1, wherein the first metal film contains at least one metal selected from the group consisting of Mn, Al, V, Zn, Nb, Zr, Cr, Y, Tc, and Re.

12. The method according to claim 1, wherein
the insulating interface film comprises at least one compound selected from the group consisting of αₓO_{y}, αₓSi_{y}O_{z}, αₓC_{y}O_{z}, and αₓF_{y}O_{z}, where a metal material of the first metal film is represented by α.

13. The method according to claim 1, wherein the first and second metal films are Mn, and the interface film comprises MnSiO.

14. A method of manufacturing a semiconductor device, comprising:
providing a first substrate comprising a first surface including a first insulating region and at least one first metal region directly adjacent to the first insulating region;
forming a first metal film on the first insulating region and the first metal region, wherein the first metal film comprises a metal other than the metal of the first metal region;
providing a second substrate comprising a second surface including a second insulating region and at least one second metal region directly adjacent to the second insulating region;
forming a first metal film on the first insulating region and the first metal region, wherein the first metal film comprises a metal other than the metal of the first metal region;
forming a second metal film on the second insulating region and the second metal region, wherein the second metal film comprises a metal other than the metal of the second metal region;
bringing the first metal film and the second metal film into contact with each other so that the first surface of the first substrate faces the second surface of the second substrate and a first portion of the first metal region faces a portion of the second insulating region, a first portion of the second metal region faces a portion of the first insulating region, and a second portion of each of the first and second metal regions face each other; and
heat treating the first substrate and the second substrate and thereby electrically connecting the second portions of the first metal region and the second metal region to each other and simultaneously forming an insulating interface film between the first insulating region and the second insulating region, between the first portion of the first metal region and the second insulating region, and between the first portion of the second metal region and the first insulating region.

15. The method according to claim 14, further comprising:
providing a barrier layer between the first metal region and the first insulating region, wherein
the insulating interface film extends over the portion of the barrier layer between the first portion of the first metal region and the first insulating region, and the insulating interface film does not extend over the portion of the barrier layer between the second portion of the first metal region and the first insulating region.

16. The method according to claim 14, wherein at least one of the first metal film and second metal film comprises a metal oxide.

17. The method according to claim 14, wherein the first metal film contains at least one metal selected from the group consisting of Mn, Al, V, Zn, Nb, Zr, Cr, Y, Tc, and Re.

18. The method according to claim 14, wherein the insulating interface film comprises at least one compound selected from the group consisting of αₓO_{y}, αₓSi_{y}O_{z}, αₓC_{y}O_{z}, and αₓF_{y}O_{z}, where a metal material of the first metal film is represented by α.

19. The method according to claim 14, wherein the first and second metal films are Mn, and the interface film comprises MnSiO.

20. The method according to claim 14, wherein the electrically connected first metal region and the second metal region includes the material of the first and second metal films therein.
